(19) United States
(12) Patent Application Publication
(10) Pub. No.: US 2008/0112224 A1
(43) Pub. Date: May 15, 2008

(54) Mini flash disk with data security function

(76) Inventors: Chung-Liang Lee, Taipei (TW); Kuang Jung Chang, Taipei (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/797,108

(22) Filed: May 1, 2007

(30) Foreign Application Priority Data
Nov. 14, 2006 (TW) 095220027

(51) Int. Cl. G11C 11/34

(52) U.S. Cl. 365/185.09

(57) ABSTRACT

A mini flash disk with data security function conforms to the hard disk specification of the Technical Committee T13 that describes the width of shell is 2.5 inches or 1.8 inches. The shell of the mini flash disk comprises a control chipset for connecting with the external connecting port, a plurality of connecting units connected with the control chipset, wherein the connecting units conform to the same interface specification with the control chipset. Consequently, the connecting units can connect with a flash device respectively for mirroring the data of the first flash device to be within the second flash device by control chipset, such that can ensure the data security for the mini flash disk.

### FIELD OF THE INVENTION

The present invention relates to a mini flash disk, and more particularly to a mini flash disk with data security function.

### BACKGROUND OF THE INVENTION

Generally, the most of hard disks are used to access data by the way of mechanical, therefore, when that is under the environment of much vibration and high moisture, the accessing of disks may occur the failure or the disks may be damaged. Accordingly, the flash memory is generated to overcome the shortcomings, which provides the advantages of high stability, quakeproof, moisture-proof, and high speed transmission, such that can be used to replace the prior disks. The flash memory has to be developed as a flash disk.

Referring to FIG. 1, the mini flash disk 10 mainly comprises an integrated drive electrical interface (IDE) 12, a control chip 14, and a flash memory 16. In accordance with the life time of the flash memory is limited, one hundred thousands times accessing for the flash memory is guaranteed only, thus, when the flash memory 16 is damaged, the data stored therein will be failure to access; therefore, the data security of the mini flash disk 10 is the most important issue at present.

Furthermore, due to the development of the storage media is fast, the weeding speed thereof is getting fast also. And, a fixed flash memory that cannot be upgraded for the different memory capacity is not suitable for the demand at present. For example, regarding to the manufactures or dealers, since the development of the storage media is fast, the price range thereof has to be larger, and the types of memory capacity have too much, further, when the stock is occurred too much accordingly, the efficiency of goods control will be affected. In another hand, regarding to the users, the demand of increasing memory capacity for the host has to be upgraded by exchanging continuously, however, the price of storage media with higher memory capacity is as higher due to the development thereof. Obviously, the usage of storage media is not flexible that cannot be adjusted the memory capacity thereof depending on the demand for users.

### SUMMARY OF THE INVENTION

It is a primary object of the present invention to provide a mini flash disk with data security function that comprises a first flash memory storage and a second flash memory storage therein, wherein further comprises a control chip used to mirror the data stored in the first flash memory storage to the second flash memory storage for ensuring the security of data, and further, the mini flash disk can be operated continuously.

It is a secondary object of the present invention to provide a mini flash disk with data security function that comprises a plurality of connecting units for being plugged in or taken out a flash memory storage, such that the mini flash disk can be with the function of exchanging the flash memory storage.

It is another object of the present invention to provide a mini flash disk with data security function that comprises a detector for detecting whether the flash memory storage is operated regularly, and further, when the flash memory storage is damaged, the detector would have a notice to users.

It is another object of the present invention to provide a mini flash disk with data security function that provides the advantages without larger volume, including higher memory capacity, higher operation speed, more reliability, and higher performance.

It is another object of the present invention to provide a mini flash disk with data security function that provides the function of exchanging flash memory storage therein, and further, providing the advantages of controlling the price of flash memory storage conveniently for dealers and adjusting the memory capacity of flash memory storage for the demand of users.

To achieve the previous mentioned objects, the present invention provides a mini flash disk with data security function, comprising a shell with width thereof conformed to the specification of the Technical Committee T13; a connecting port provided on the shell for being as an external connecting interface; a control chip provided within the shell and connected to the connecting port; and a plurality of connecting units provided within the shell and connected to the control chip, wherein the connecting units are with the same interface specification and set up a first flash memory storage and a second flash memory storage respectively, wherein the control chip can be used to mirror the data stored in the first flash memory storage to the second flash memory storage.

### BRIEF DESCRIPTION OF THE DRAWINGS

It will be understood that the figures are not to scale since the individual layers are too thin and the thickness differences of various layers too great to permit depiction to scale.

FIG. 1 is a block diagram of prior art mini flash disk;

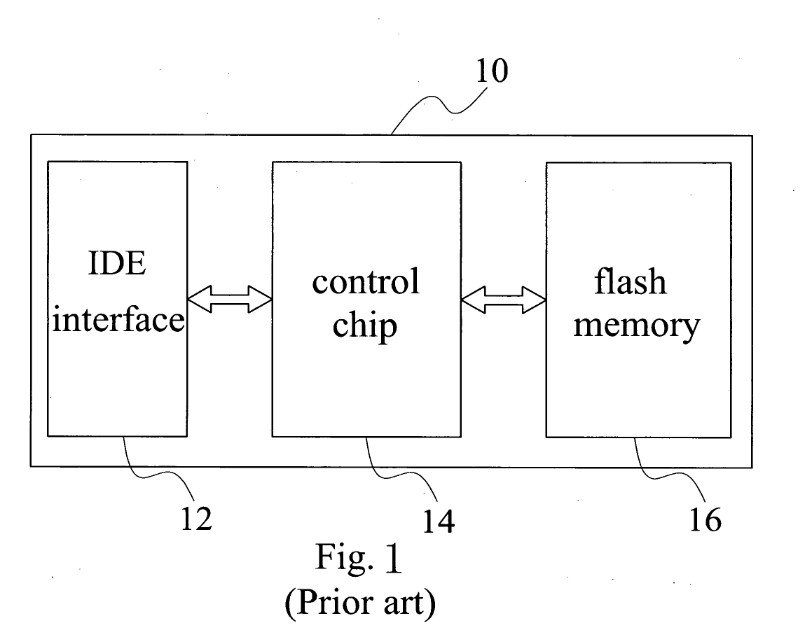

FIG. 2 is a block diagram of a preferred embodiment of the present invention;

FIG. 3A is an internal structure view of a preferred embodiment of the present invention;

FIG. 3B is an internal operation view of a preferred embodiment of the present invention;

FIG. 4 is a cross-sectional view of a circuit of a preferred embodiment of FIG. 3A;

FIG. 5 is a diagram of a preferred embodiment of the present invention with two light emitting diodes on the front of the shell; and

FIG. 6 is a block diagram of another preferred embodiment of the present invention.

### DETAILED DESCRIPTION OF THE INVENTION

The structural features and the effects to be achieved may further be understood and appreciated by reference to the presently preferred embodiments together with the detailed description.

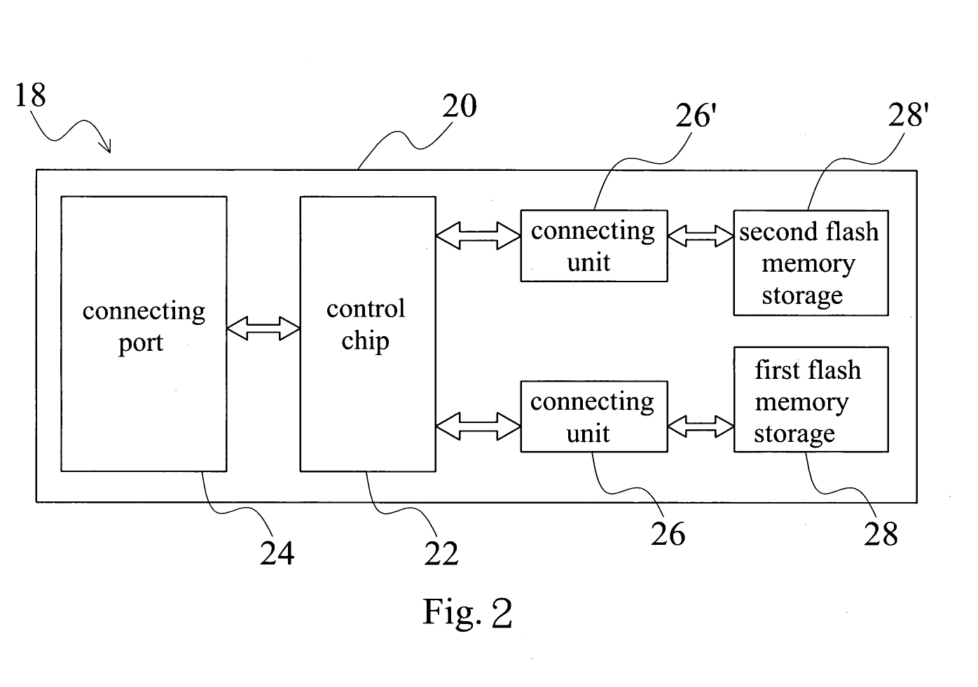

Referring to FIG. 2, is a block diagram of a preferred embodiment of the present invention. The mini flash disk 18 conforms to the hard disk specification of the International Technical Committee T13 that discloses the width of hard disk should be 2.5 inches or 1.8 inches. The mini flash disk 18 comprises a shell 20, a control chip 22, a connecting port 24, and two connecting units 26 and 26′, wherein the control chip 22, the connecting port 24, and two connecting units 26 and 26′ are provided within the shell 20, wherein the control chip 22 is connected with the connecting port 24 and the connecting units 26 and 26′. The connecting port 24 can be selected as an Integrated Drive Electronic (IDE) interface, a Universal Serial Bus (USB) interface, a Small Computer Standard Interface (SCSI) interface, an Advanced Technology Attachment (ATA) interface, or a Serial ATA (SATA) interface for being as the external connecting interface that can be used to install into an electrical equipment or a host. The two connecting units are with the same interface specification, such as an ATA interface, a USB interface, a SATA interface, an ATA interface, or SCSI interface, and used to set up a first flash memory storage 28 and a second flash memory storage 28′ respectively. The first flash memory storage 28 and the second flash memory storage 28′ comprises at least one connector that conforms the same interface specification with the connecting units 26 and 26′, a control chip, and at least one control chip. For example, if the connecting units 26 and 26′ are with the same USB interface, the first flash memory storage 28 and the second flash memory storage 28′ are as the flash memory storage with USB interface.

The control chip 22 can be used to control the first flash memory storage 28 and the second flash memory storage 28′ that mirrors the data stored in the first flash memory storage 28 to the second flash memory storage 28′ for ensuring the data security within the mini flash disk 18. That is, the first flash memory storage 28 and the second flash memory storage 28′ are formed as the type 1 of Redundant Array of Independent Disks (RAID-1), which is controlled by the control chip 22. The control chip 22 can be used to control the data transmission tunnels of these two flash memory storages, therefore, when the mini flash disk 18 received the data from the connecting port 24, the data will be stored in the first flash memory storage 28 and the second flash memory storage 28′ at the same time, thus, while the first flash memory storage 28 is damaged that results to the failure of data accessing according to out of life time or other reasons, the control chip 22 will control to access data from the second flash memory storage 28′, such that the operation of the mini flash disk 18 can be proceeded surely that is helpful to increase the product reliability.

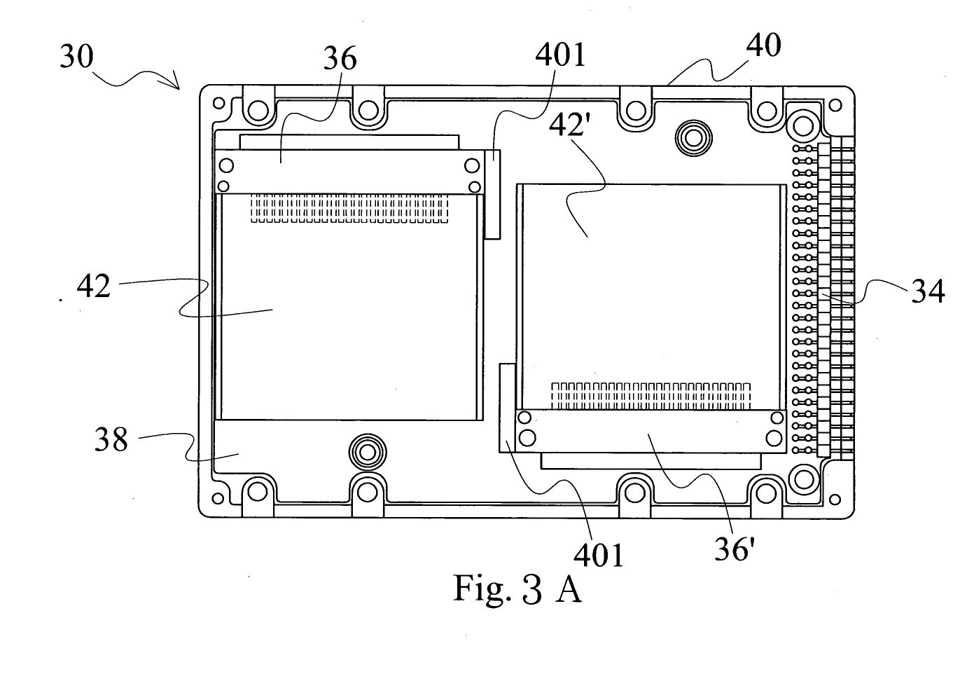

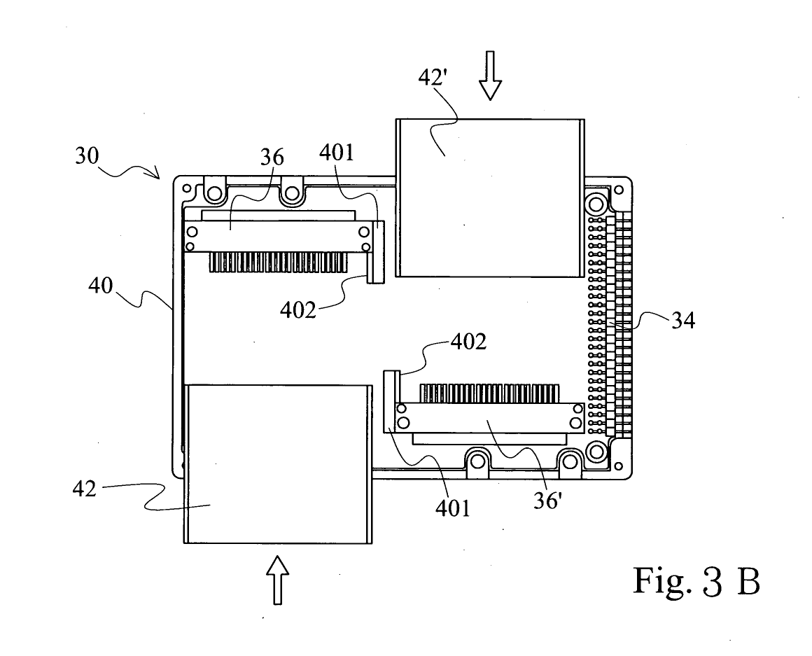

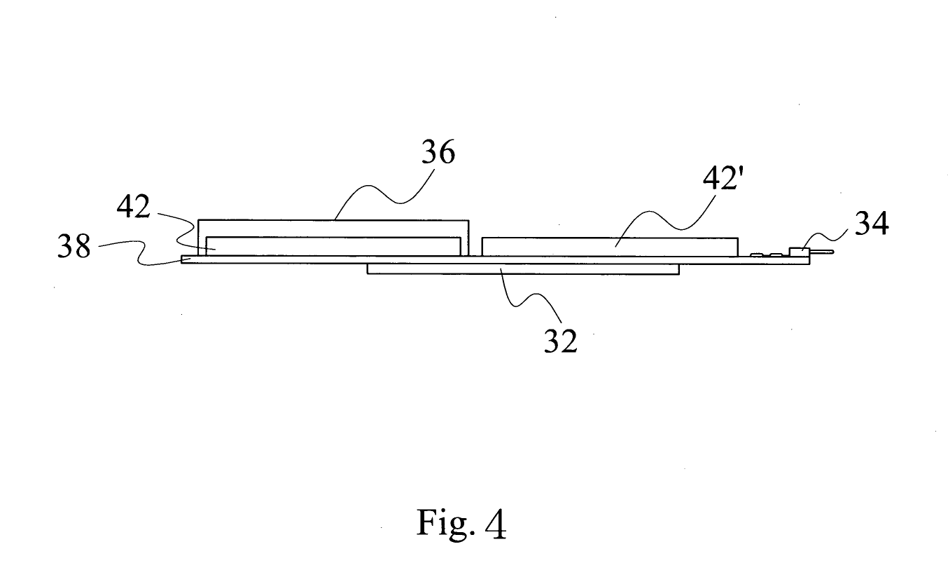

Referring to FIG. 3A to FIG. 3B, are respectively an internal structure view and an internal operation view of a preferred embodiment of the present invention, and further referring to FIG. 4, is a cross-sectional view of a circuit of a preferred embodiment of FIG. 3A. The mini flash disk 30 comprises a control chip 32, an IDE interface 34, and two ATA interfaces 36 and 36′ that are integrated into a circuit board 38, besides, the circuit board 38 has been provided relative electrical elements already (not shown on the Figs.), accordingly, the circuit board 38 is within the shell 40. The mini flash disk 30 is with the IDE interface 34 for communicating to an electrical equipment or a host, and the control chip 32 therein is provided to be as the main control core. As well as, the control chip 32 is used to control the data accessing by the internal command thereof that controls to read or store data, especially, when the data is going to store, the data mirroring has to be executed.

In accordance with the ATA interface 36 and 36′ and the flash memory storage are substantially separable, the flash memory storage can be exchanged due to the damaged or the more memory capacity demand, such as exchanging failure CF memory card 42 and 42′, SD memory card, or USB flash memory device. That is, the flash memory storage can be taken out from the ATA interface 36 and 36′, and a new flash memory storage for demanding can be plugged therein.

Accordingly, due to fasten the first flash memory storage 42 and the second flash memory storage 42′ within the shell 40, the shell 40 further comprises two fastening devices 401 provided between the first flash memory storage 42 and the second flash memory storage 42′. The fastening devices 401 comprise wedging bodies provided on the side of the fastening devices 401. The wedging bodies 402 can be used to wedge the sides of the first flash memory storage 42 and the second flash memory storage 42′, such that these two flash memory storages 42 and 42′ can be within the mini flash disk 18 and 30 fixedly, otherwise, which can be exchanged depending on demand.

Each fastening device 401 has single wedging body 402 provided on one side thereof, and further, two wedging bodies 402 are provided on the shell 40 in accordance with the same straight line. The first flash memory storage 42 and the second flash memory storage 42′ are plugged into the fastening device 401 in different directions respectively; accordingly, such design for fastening is regarding to the reason of saving the space where the wedging bodies 402 have placed in the shell 40, thus, the width of shell 40 can be fit in accordance with the size of 2.5 inches.

At the present invention, a structure with more flexible memory capacity and demand exchanging according to the flash memory storage is disclosed. Furthermore, the mini flash disk can be used to access data with multiplexing many flash memory storages, such that provides the advantages of higher transmission speed, performance, reliability. Thus, regarding to the dealer for selling storage media specially, the unstable price and stock thereof can be efficiently controlled by exchanging the flash memory storage properly even through the development of high memory capacity storage media is such fast. Certainly, a more cheap and memory capacity for the flash memory storage media has been provided for consumer.

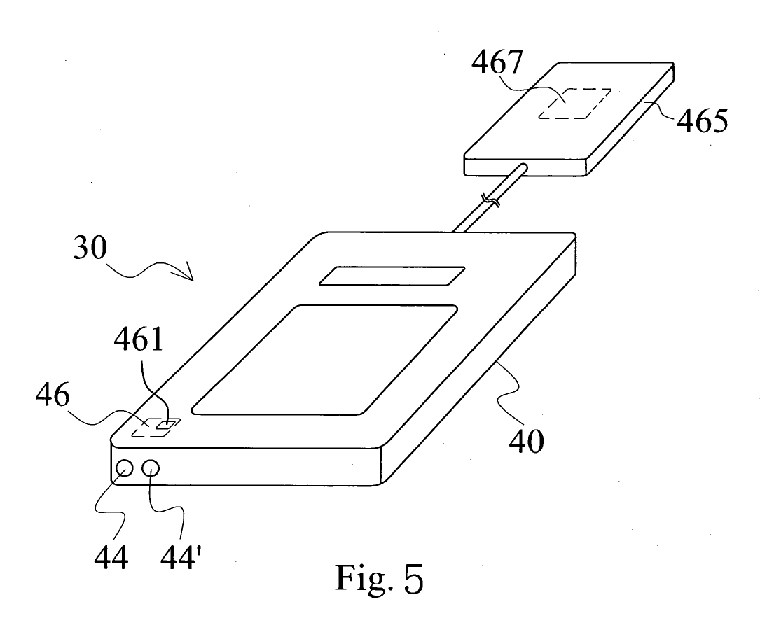

Referring to FIG. 5, is a diagram of a preferred embodiment of the present invention with two light emitting diodes on the front of the shell. The shell 40 of the mini flash disk 30 comprises a detector 46 thereon, which is electrically connected to the control chip 32 and the connecting units 36 and 36′. When any of the flash memory storages 42 or 42′ is failure, the detector 46 would have a notice for users to exchange. For example, the detector 46 is provided a default detecting program therein, such that the detector 46 can be used to detect whether the flash memory storage 42 or 42′ is operated regularly, when one of the flash memory storages is failure, a notice information 461 will be had to notice announce management device 465 that is connected with the mini flash disk 30, such as a computer, a telephone, or a network device, thereafter, the announce management device 465 will have a notice massage 467 to notice users for exchanging, such as a sound, an email, or a new-letter.

The detector 46 can be selected for comprising at least one directing element, such as shown on the FIG. 5 that shows two Light emitting diodes (LED) 44 and 44′. Otherwise, the directing elements 44 and 44′ can be also as a Liquid Crystal Display (LCD) panel, therefore, the operation status according to the ATA interface 36 and 36′ within the mini flash disk 30 can be displayed by the directing elements. Certainly, once any of flash memory storages 42 or 42′ is failure, the notice massage will be had to users for exchanging properly.

Since the present invention mini flash disk has the function of mirroring, while the flash memory storage 42 is failure, the data stored therein will not be lost, which is the cause of that the data has stored in another flash memory storage 42′ already, such that the data security is provided, and the mini flash disk 30 can work regularly, wherein the failure flash memory storage within the mini flash disk 30 is waiting for exchanging. Accordingly, once the failure flash memory storage 42 is exchanged, the data stored in another flash memory storage 42′ can be mirrored to the new one surely.

In accordance with the preferred embodiment of the present invention, the flash memory storage 42 or 42′ is with the hot plugging function, therefore, when the failure flash memory storage is during exchanging, the equipment or host will not be required to power off.

Regarding to the above mentioned structure of the present invention, the memory capacity of the mini flash disk can be exchanged flexibly. Thus, the present invention surely overcomes the shortcomings of prior art that has fixed memory capacity only and cannot be exchanged flexibly, and further, the present invention provides a mini flash disk that not only can be exchanged flexibly, and also has the advantages of more memory capacity, higher transmission speed, higher reliability, and higher performance, since the original volume of the mini flash disk is without increasing.

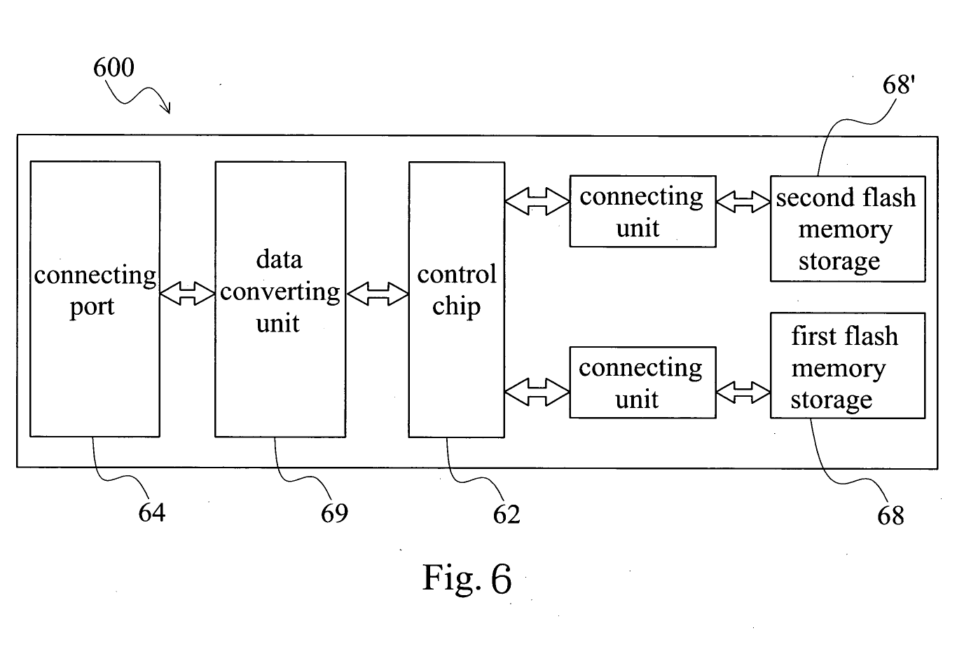

Referring to FIG. 6, is a block diagram of another preferred embodiment of the present invention. The first flash memory storage 68 and the second flash memory storage 68′ can be selected as other types of flash memory, such as various NOR types or NAND types flash memory. Furthermore, once the selected flash memory is not supportable for the connecting port 64 in accordance with the data transmission type, the mini flash disk 600 comprises a data converting unit 69 electrically connected with the connecting port 64 and the control chip 62 for converting the data that is transmitted between two terminals of the data converting unit 69 for conforming the specification.

While this invention has been described with reference to illustrative embodiments, this description is not intended to be construed in a limiting sense. Various modifications of the illustrative embodiments, as well as other embodiments of the invention, which are apparent to persons skilled in the art to which the invention pertains are deemed to lie within the spirit and scope of the invention.

I claim:

1. A mini flash disk with data security function, comprising:
a shell with width thereof conformed to the specification of the Technical Committee T13;
a connecting port provided on said shell for being as an external connecting interface;
a control chip provided within said shell and connected to said connecting port; and
a plurality of connecting units provided within said shell and connected to said control chip, wherein said connecting units are with the same interface specification and set up a first flash memory storage and a second flash memory storage respectively, wherein said control chip can be used to mirror the data stored in said first flash memory storage to said second flash memory storage.

2. The mini flash disk of claim 1, wherein said shell further comprises two fastening devices fixed between said first flash memory storage and said second flash memory storage.

3. The mini flash disk of claim 2, wherein said fastening device further comprises a wedging body provided on the side of said fastening device.

4. The mini flash disk of claim 1, wherein said connecting port can be selected from one of an Integrated Drive Electronic (IDE) interface, a Universal Serial Bus (USB) interface, a Small Computer Standard Interface (SCSI) interface, an Advanced Technology Attachment (ATA) interface, and a Serial ATA (SATA) interface.

5. The mini flash disk of claim 1, wherein said connecting units can be as the same interface specification, such as an ATA interface, a USB interface, a SATA interface, or a SCSI interface.

6. The mini flash disk of claim 1, wherein said flash memory storage can be selected from one of a Compact Flash (CF) memory card, a USB flash device, and a Secure Digital (SD) memory card.

7. The mini flash disk of claim 1, wherein said flash memory storage comprises at least one connector, a control chip, and at least one flash memory chip.

8. The mini flash disk of claim 1, wherein a circuit is integrated with said control chip, said connecting port, and said connecting units.

9. The mini flash disk of claim 1, wherein further comprises a detector electrically connected with said control chip and said connecting units.

10. The mini flash disk of claim 9, wherein said detector further comprises at least one directing element for noticing whether said flash memory storage on said connecting units is operated regularly.

11. The mini flash disk of claim 10, wherein said directing element can be selected from one of a Light Emitting Diode (LED), a Liquid Crystal Display (LCD), and a combination thereof.

12. The mini flash disk of claim 9, wherein said detector can have a notice information and be connected with an announcing management device for having a notice massage.

13. The mini flash disk of claim 1, wherein further comprises two fastening devices provided on the two sides within said shell, each of fastening devices comprising a wedging body provided on one side thereof, wherein every two wedging bodies are provided on said shell in accordance with the same straight line that results to said first flash memory storage and said second flash memory storage connecting to said connecting units in different directions respectively.

14. The mini flash disk of claim 1, wherein the width of said shell conforms to the hard disk specification of the Technical Committee T13 that is one of a 2.5 inches and 1.8 inches.
